(19) United States
(12) Patent Application Publication
(10) Pub. No.: US 2015/0206716 A1
(43) Pub. Date: Jul. 23, 2015

(54) PLASMA GENERATING APPARATUS

(71) Applicant: SAMSUNG ELECTRONICS CO., LTD., SUWON-SI (KR)

(72) Inventors: HYUNGJOON KIM, Suwon-Si (KR); Vasily Pashkovskiy, Suwon-Si (KR); Sang-Heon Lee, Seongnam-si (KR); Sang-Jean Jeon, Suwon-Si (KR); Doug-Yong Sung, Seoul (KR); Yun-Kwang Jeon, Seoul (KR); Bong-Seong Kim, Yongin-Si (KR)

(21) Appl. No.: 14/601,878

(22) Filed: Jan. 21, 2015

(30) Foreign Application Priority Data
Jan. 22, 2014 (KR) 10-2014-0007935

(51) Int. Cl. H01J 37/32; C23C 14/22; C23C 16/505

(52) U.S. Cl. CPC H01J 37/32146; H01J 37/32082; H01J 37/32091; H01J 37/321; H01J 37/3211; C23C 16/505; C23C 14/22

(57) ABSTRACT

A plasma generating apparatus includes a chamber that encloses a reaction space that is isolated from the outside; a wafer chuck disposed in a lower portion of the chamber; a plasma generation unit disposed in an upper portion of the chamber; a first radio-frequency (RF) power source that supplies RF power to the plasma generation unit; a first matching unit interposed between the first RF power source and the plasma generation unit; a second RF power source that supplies RF power to the wafer chuck; and a second matching unit interposed between the second RF power source and the wafer chuck. The first RF power source supplies a first pulse power level and a different second pulse power level at different times.

### CROSS-REFERENCE TO RELATED APPLICATIONS

This application claims priority under 35 U.S.C. §119 from Korean Patent Application No. 10-2014-0007935, filed on Jan. 22, 2014, in the Korean Intellectual Property Office, and all the benefits accruing therefrom, the contents of which are herein incorporated by reference in their entirety.

### BACKGROUND

Embodiments of the inventive concept are directed to a plasma generating apparatus, and more particularly, to a plasma generating apparatus that is operated by RF power.

When wafer processes such as etching and deposition are performed using a radio-frequency (RF) pulse plasma generating apparatus, an electron temperature may be reduced to be lower than a case in which a continuous wave (CW) plasma is used. This may reduce the possibility of the wafer being damaged due to excessive decomposition of injected reactive gas. To apply RF pulse plasma to a semiconductor manufacturing process, a stable plasma having a secured reproducibility needs to be formed by reducing reflected power.

### SUMMARY

Embodiments of the inventive concept may provide a plasma generating apparatus capable of operating a pulse mode stable plasma with a RF pulse plasma in a semiconductor manufacturing process.

According to an aspect of the inventive concept, there is provided a plasma generating apparatus including a chamber that encloses a reaction space that is isolated from the outside; a wafer chuck disposed in a lower portion of the chamber; a plasma generation unit disposed in an upper portion of the chamber; a first RF power source that supplies RF power to the plasma generation unit; a first matching unit interposed between the first RF power source and the plasma generation unit; a second RF power source that supplies RF power to the wafer chuck; and a second matching unit interposed between the second RF power source and the wafer chuck. The first RF power source supplies a first pulse power level and a different second pulse power level at different times.

The second pulse power level may be greater than the first pulse power level. A duration time of the second level pulse power may be from about 0.1 to about 1 ms. The second pulse power level may be supplied within about 1 ms after the start of each pulse generated by the first RF power.

The first RF power source and the second RF power source may be synchronized with each other. The plasma generating apparatus may further include a power source connection unit that is connected to the first RF power source and the second RF power source to synchronize the first RF power source and the second RF power source.

The first RF power source may be a capacitively coupled plasma (CCP) source. Alternatively, the first RF power source may be an inductively coupled plasma (ICP) source. The plasma generation unit may further include an antenna that is connected to the first RF power source with the first matching unit interposed therebetween, and an insulating plate between the antenna and the wafer chuck.

According to another aspect of the inventive concept, there is provided a plasma generating apparatus including: a chamber that encloses a reaction space that is isolated from the outside; a wafer chuck disposed in a lower portion of the chamber; a plasma generation unit disposed in an upper portion of the chamber; a first RF power source that supplies RF power to the plasma generation unit; a first matching unit interposed between the first RF power source and the plasma generation unit; a second RF power source that supplies RF power to the wafer chuck; and a second matching unit interposed between the second RF power source and the wafer chuck. The first RF power source supplies a first pulse power frequency and a different second pulse power frequency at different times.

The second pulse power frequency may be applied when each pulse generated by the first RF power source starts, to reduce a time for matching impedance between the first RF power source and the plasma generation unit.

A frequency of the second pulse power frequency may be higher than a frequency of the first pulse power frequency. A duration of the second pulse power frequency may be from about 0.1 to about 1 ms. The first RF power source may supply a first pulse power level and a different second pulse power level at different times. A duration of the second pulse power frequency may be the same as a duration of the second pulse power level.

According to another aspect of the inventive concept, there is provided a method of generating plasma in a plasma generating apparatus, including supplying a reactive gas into a chamber of the a method of generating plasma from a gas supply unit; and applying a first RF power in a pulse mode from a first RF power source to a plasma generating unit inside the chamber, where an electric field generated by the plasma generating unit converts the reactive gas into a plasma state. A first RF power pulse includes a first pulse and a different second pulse at different times during an on-time of each pulse, and plasma turn-on and turn-off operations are repeatedly performed based on the pulse frequencies.

The first pulse may have a first power pulse level and the second pulse may have a second power pulse level, wherein the a second power pulse level is greater than the first power pulse level, wherein the second pulse is applied within a first time interval of the start of each first RF power pulse.

The first time interval may be 1 ms.

The first pulse may have a first power pulse frequency and the second pulse may have a second power pulse frequency. The second power pulse frequency is higher than the first power pulse frequency, wherein the second pulse is applied at the start of each plasma pulse generated by the first RF power pulse.

The method of claim 16, further comprising applying a second RF power in a pulse mode from a second RF power source to a wafer chuck inside the chamber, wherein the second RF power is synchronized with the first RF power, wherein a duty ratio of the second RF power is equal to a duty ratio of the first RF power.

### BRIEF DESCRIPTION OF THE DRAWINGS

FIG. 1 illustrates a plasma generating apparatus according to an embodiment of the inventive concept.

FIG. 2 illustrates a plasma generating apparatus according to another embodiment of the inventive concept.

FIG. 3 illustrates a plasma generating apparatus according to another embodiment of the inventive concept.

FIG. 4 illustrates a plasma generating apparatus according to another embodiment of the inventive concept.

FIG. 5 illustrates an example of a first RF power source of a plasma generating apparatus according to the inventive concept being operated in a pulse mode.

FIG. 6 illustrates another example of a first RF power source of a plasma generating apparatus according to the inventive concept being operated in a pulse mode.

FIG. 7 illustrates an example of a first RF power source and a second RF power source of a plasma generating apparatus according to the inventive concept being operated in a synchronized pulse mode.

FIG. 8 illustrates another example of a first RF power source and a second RF power source of a plasma generating apparatus according to the inventive concept being operated in a synchronized pulse mode.

FIG. 9 is a graph of an example of a first RF power source of a plasma generating apparatus according to the inventive concept being operated in a pulse mode.

FIG. 10 is a graph of another example of a first RF power source of a plasma generating apparatus according to the inventive concept being operated in a pulse mode.

FIGS. 11A and 11B illustrate an improvement of pulse plasma generation characteristics of a plasma generating apparatus according to an embodiment of the inventive concept.

### DETAILED DESCRIPTION OF EXEMPLARY EMBODIMENTS

The present inventive concept will be described more fully with reference to the accompanying drawings.

The inventive concept may, however, be embodied in many different forms and should not be construed as limited to the exemplary embodiments set forth herein. In the drawings, lengths and sizes of layers and regions may be exaggerated for clarity. Herein, when one value is described as being about equal to another value, e.g. “a duration may be from about 0.1 to about 1 ms”, it is to be understood that the values are equal to each other to within a measurement error, or if measureably unequal, are close enough in value to be functionally equal to each other as would be understood by a person having ordinary skill in the art.

A plasma generating apparatus according to embodiments of the inventive concept may use a capacitively coupled plasma (CCP) system in which wafers are arranged at a point having a radio-frequency (RF) voltage applied thereto, a magnetically-enhanced RIE (CCP-MERIE) system in which the possibility of ion generation is increased by applying a magnetic field to a plasma space to perform etching, an electron cyclotron resonance (ECR) system in which resonance is generated by applying a microwave frequency thereon to ionize neutral particles, a transformer coupled plasma (TCP) system in which an RF coil is used that is only wound around an upper portion of a process chamber, an inductively coupled plasma (ICP) system in which an RF coil is used that is wound around a side surface of a process chamber, a helical plasma system in which a spiral RF coil is used, a high density plasma (HDP) system in which a plasma generating portion and an ion energy adjusting portion are independently controlled, etc. However, embodiments of the inventive concept are not limited thereto, and a plasma generating apparatus may use any system in which the plasma generating apparatus may apply pulsed RF power.

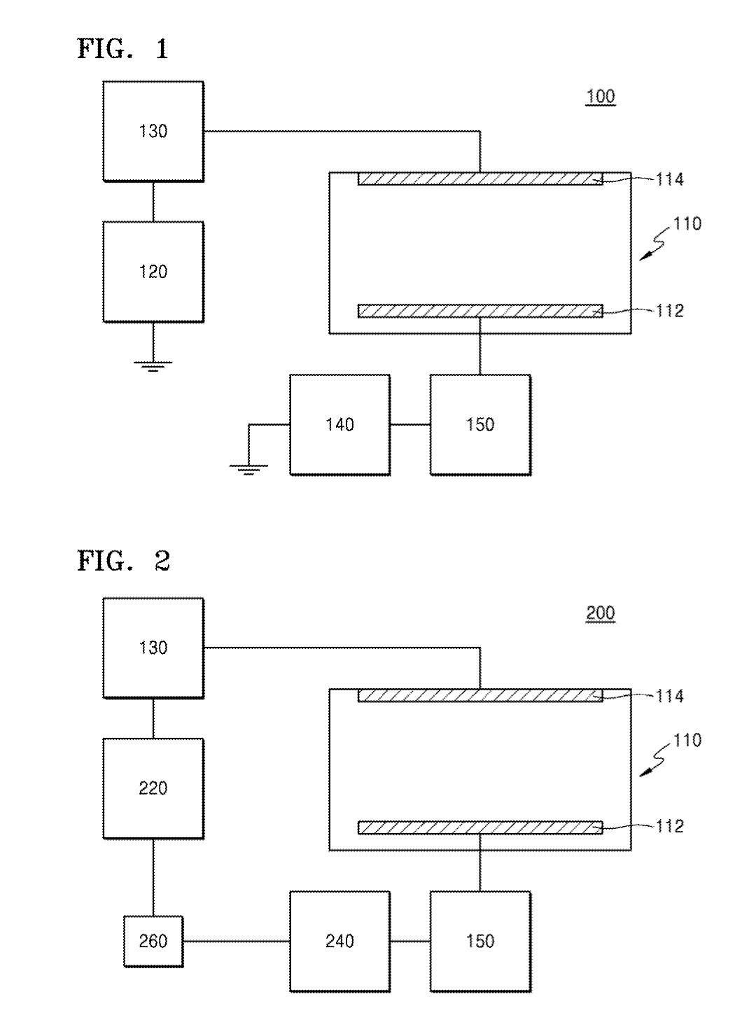

FIG. 1 illustrates a plasma generating apparatus 100 according to an embodiment of the inventive concept.

Referring to FIG. 1, the plasma generating apparatus 100 includes a chamber 110 provided with a wafer chuck 112 and a plasma generation unit 114, a first RF power source 120, a first matching unit 130, a second RF power source 140, and a second matching unit 150.

The chamber 110 provides a plasma reaction space that is isolated from the outside, forms an enclosed space having a predetermined size therein that may be grounded, and which may have various sizes and forms depending on the size of a wafer on which a process is to be performed and on process characteristics.

In some embodiments, the chamber 110 may be formed of a metal, an insulator, or a combination thereof. In another embodiment, the inside of the chamber 110 may be coated with an insulator. The chamber 110 may have a rectangular parallelepiped shape or a cylindrical shape, but embodiments of the inventive concept are not limited thereto.

In some embodiments, the chamber 110 may include a gas exhaust unit and a gas supply unit. The gas supply unit may supply a reactive gas to the chamber 110, and exhaust gases may be expelled through the gas exhaust unit to maintain the chamber 110 in a vacuum state.

The wafer chuck 112 may be disposed in a lower portion of the chamber 110. In some embodiments, the wafer chuck 112 may be an electrostatic chuck (ESC) that adsorbs and supports a wafer by an electrostatic force. In another embodiment, the wafer chuck 112 may be a vacuum chuck that adsorbs and supports a wafer by a vacuum pressure, or may be a mechanical clamping type chuck. The wafer chuck 112 may be provided with a heater that heats the wafer to a process temperature.

The wafer chuck 112 may be connected to the second RF power source 140 that applies RF power to generate a plasma from the reactive gas. The RF power supplied by the second RF power source 140 may be a bias power. The RF power received from the second RF power source 140 is supplied to the wafer chuck 112, and the reactive gas diffused within the chamber 110 changes into a plasma state to react with a wafer on the wafer chuck.

That is, the reactive gas diffuses within the chamber 110 and is changed into a plasma state by the RF power applied to the wafer chuck 112. The plasma comes into contact with a surface of the wafer on the wafer chuck 112 to physically or chemically react with the wafer. Wafer processes such as plasma annealing, etching, plasma-enhanced chemical vapor deposition, physical vapor deposition, and plasma cleaning may be performed through such reactions.

The plasma generation unit 114 transmits power generated by the first RF power source 120 into the chamber and may be disposed in an upper portion of the chamber 110.

The plasma generation unit 114 may be connected to the first RF power source 120 that applies RF power to generate a plasma from the reactive gas. The RF power supplied by the first RF power source 120 may be a source power. The RF power is applied from the first RF power source 120 to the plasma generation unit 114, and thus the reactive gas diffused within the chamber 110 changes into a plasma state to react with a wafer to be disposed on the wafer chuck 112.

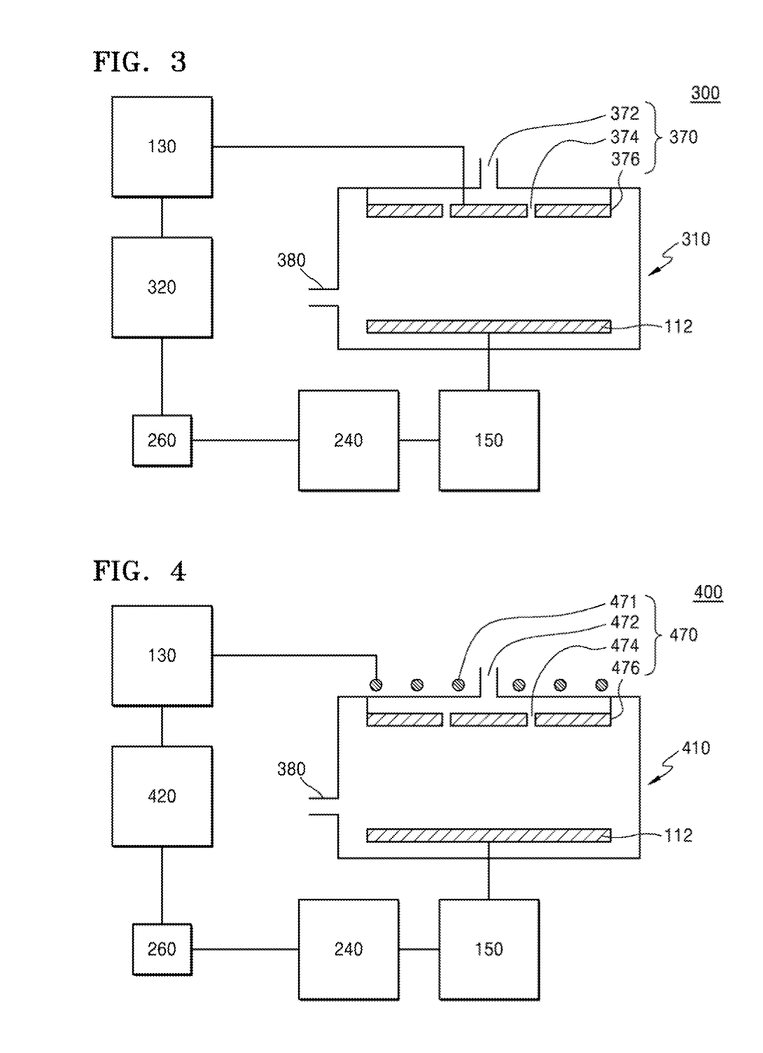

The plasma generation unit 114 may include an electrode or an antenna that is connected to the first RF power source 120. The reactive gas changes into a plasma state within the chamber 110 through the RF power supplied by the first RF power source 120 to the electrode or antenna, which will be described in detail with reference to FIGS. 3 and 4.

The first RF power source 120 is connected to the plasma generation unit 114 to apply the RF power to the plasma generation unit 114. The first matching unit 130 is interposed between the first RF power source 120 and the plasma generation unit 114 to perform impedance matching.

The second RF power source 140 is connected to the wafer chuck 112 to apply RF power to the wafer chuck 112. Similar to the first matching unit 130, the second matching unit 150 is interposed between the second RF power source 140 and the wafer chuck 112 to perform impedance matching.

In some embodiments, a role of the RF power supplied by the first RF power source 120 connected to the plasma generation unit 114 is to ignite the plasma, and a role of the RF power supplied by the second RF power source HO connected to the wafer chuck 112 is to control the plasma. That is, RF power is supplied to both the plasma generation unit 114 and the wafer chuck 112.

In some embodiments, at least one of the first RF power source 120 and the second RF power source 140 may operate in a pulse mode. In this manner, RF power is pulsed, and thus a pulse plasma may be formed. That is, a plasma is generated during an on-time of a pulse, and the plasma dissipates during an off-time. A pulse plasma may be used in wafer processing, which may have a lower electron temperature than a case in which CW plasma is used, thereby reducing the possibility of a wafer being damaged due to excessive decomposition of the injected reactive gas.

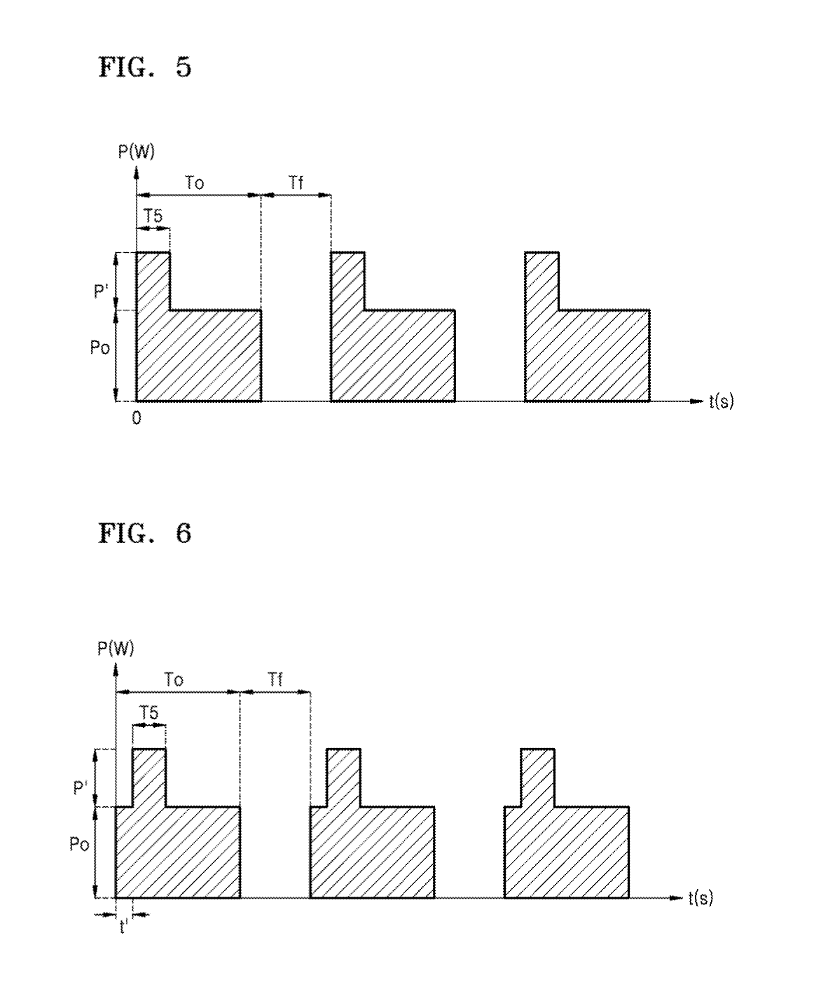

In some embodiments, the first RF power source 120 supplies a first level pulse power and a second level pulse power at different times, and the first level pulse power and the second level pulse power may have different power levels. The first level pulse power and the second level pulse power will be described below in detail with reference to FIGS. 5 and 6.

The first RF power source 120 supplies different power levels at different times, which may suppress effects due to load and a high aspect ratio that may be associated with wafer processing, and to reduce reflected power even when there are large changes in the chamber impedance, to more stably apply RF power. That is, it is possible to form a stable plasma with a secured reproducibility by suppressing delays in plasma formation due to reflected power caused by operating an RF power source in a pulse mode.

In addition, different power levels may be supplied at different times using one RF power source, and thus a high frequency RF power source capable of forming a stable pulse plasma, such as a 27.12 to 100 MHz power source, a pulse modulator and a matcher for automatic matching are not additionally required. That is, it is possible to reduce installation and operation costs of an RF system by using a simpler plasma generating apparatus.

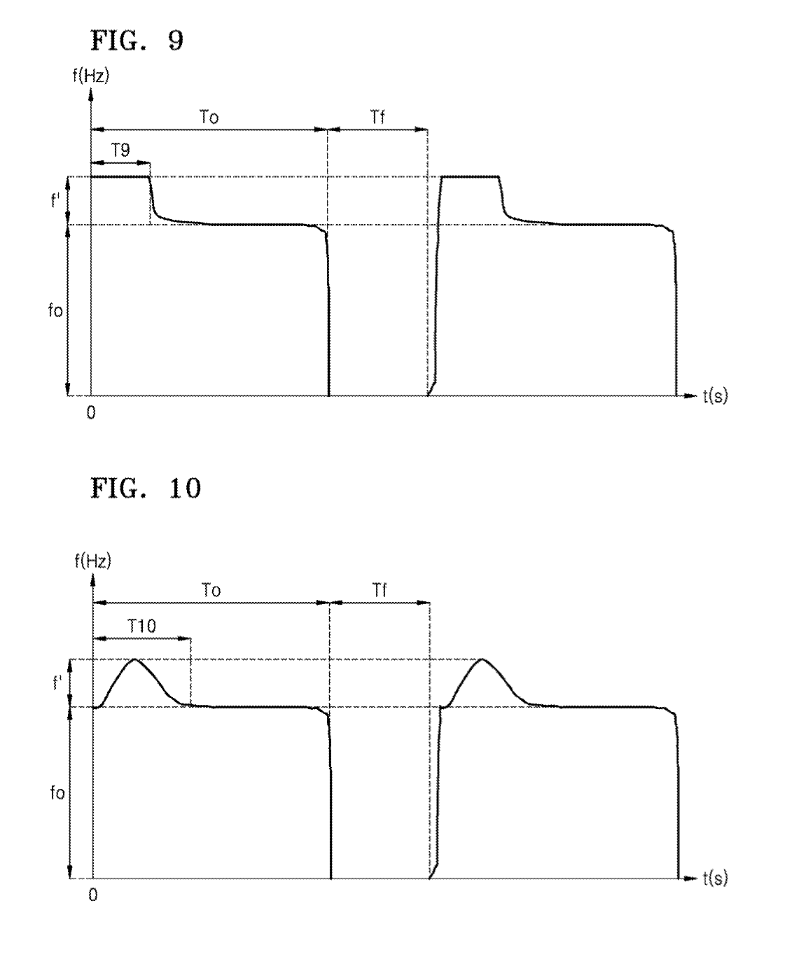

In some embodiments, the first RF power source 120 supplies a first power frequency and a second power frequency at different times, and the first power frequency and the second power frequency may have different frequency values, respectively. The first power frequency and the second power frequency will be described below in detail with reference to FIGS. 9 and 10.

The first RF power source 120 supplies power having different frequencies at different times, which may reduce a time for matching impedance between the first RF power source 120 and the plasma generation unit 114.

Specifically, an impedance Zc of a capacitor is inversely proportional to a frequency f and a capacitance C, as shown by Equation 1. Here, j denotes the imaginary number satisfying j²=−1.

$${Z}_{c} = - j \frac{1}{2 π fC} \qquad ( 1 )$$

When impedance is matched by using motor power to adjust the capacitance C, physical limitations of the motor limit how quickly the impedance may be matched. Accordingly, the first RF power source 120 supplies pulse power having different frequencies at different times during an on-time of a pulse, that is, the pulse power has a frequency f required to match the impedance, which may reduce a time for matching impedance between the first RF power source 120 and the plasma generation unit 114.

The first matching unit 130 is interposed between the first RF power source 120 and the plasma generation unit 114 to perform impedance matching between the first RF power source 120 and the plasma generation unit 114. Similarly, the second matching unit 150 is interposed between the second RF power source 140 and the wafer chuck 112 to perform impedance matching between the second RF power source 140 and the wafer chuck 112.

FIG. 2 illustrates a plasma generating apparatus 200 according to another embodiment of the inventive concept. In FIG. 2, the same reference numerals as in FIG. 1 denote the same components, and for simplicity of description, a repeated description thereof will be omitted.

Referring to FIG. 2, the plasma generating apparatus 200 includes a chamber 110 provided with a wafer chuck 112 and a plasma generation unit 114, a first RF power source 220, a first matching unit 130, a second RF power source 240, a second matching unit 150, and a power source connection unit 260.

The first RF power source 220 and the second RF power source 240 may be operated in synchronization with each other. In some embodiments, the plasma generating apparatus 200 may include a power source connection unit 260 that connects the first RF power source 220 and the second RF power source 240 to mutually synchronize the first RF power source 220 and the second RF power source 240.

In some embodiments, the power source connection unit 260 may be embedded in the first RF power source 220. In other embodiments, the power source connection unit 260 may be embedded in the second RF power source 240.

An RF power source of any one of the first RF power source 220 and the second RF power source 240 may be a lead or master RF power source, while an RF power source of the other one may be a follower or slave RF power source.

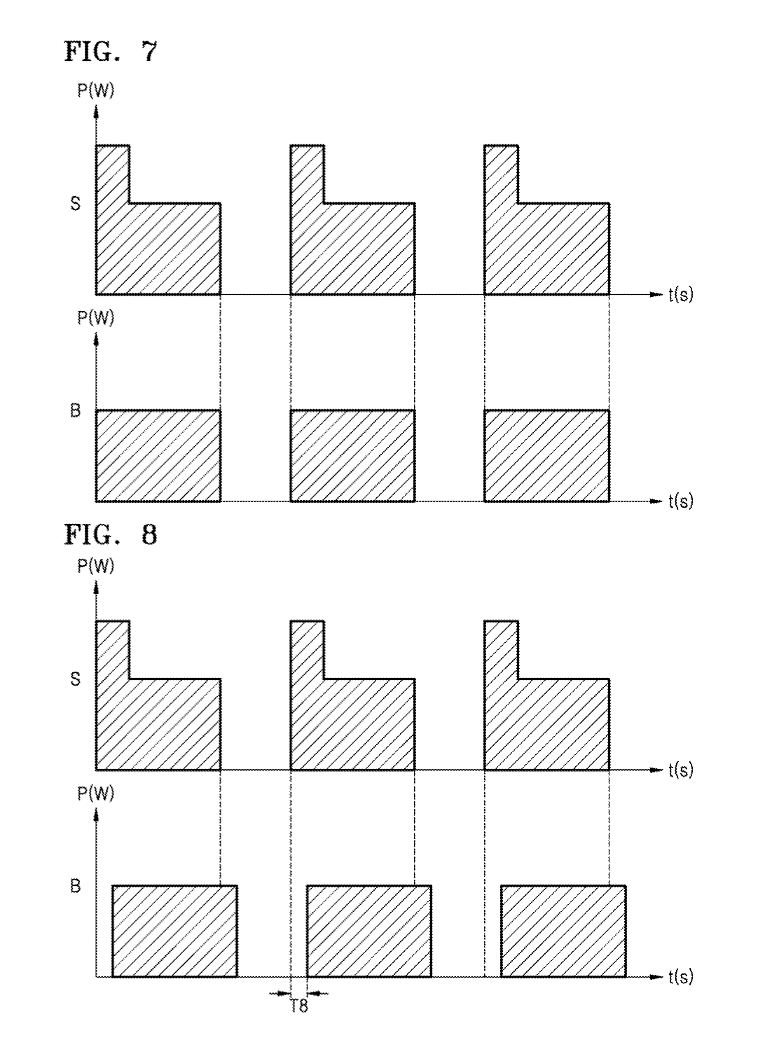

Pulse power of the first RF power source 220 and the second RF power source 240 may be completely synchronized, shown in FIG. 7, or may have a targeted phase difference, shown in FIG. 8, through the power source connection unit 260.

FIG. 3 illustrates a plasma generating apparatus 300 according to another embodiment of the inventive concept. In FIG. 3, the same reference numerals as in FIGS. 1 and 2 denote the same components, and for simplicity of description, a repeated description thereof will be omitted.

Referring to FIG. 3, the plasma generating apparatus 300 includes a chamber 310, a first RF power source 320, a first matching unit 130, a second RF power source 240, a second matching unit 150, and a power source connection unit 260.

A wafer chuck 112 may be disposed in a lower portion of the chamber 310, and a plasma generation unit 370 may be disposed in an upper portion of the chamber 310.

In some embodiments, the plasma generation unit 370 includes a gas supply unit 372, nozzles 374, and a source electrode 376.

As illustrated in FIG. 3, the gas supply unit 372 may be integrally formed with the source electrode 376. However, embodiments of the inventive concept are not limited thereto, and the gas supply unit 372 may be disposed outside of the chamber 310 separate from the source electrode 376.

The gas supply unit 372 may supply a reactive gas to the chamber 310 through the nozzles 374, and exhaust gas may be expelled through a gas exhaust unit 380 disposed in the chamber 310 to maintain the chamber 110 in a vacuum state.

In some embodiments, the first RF power source 320 may be a capacitively coupled plasma (CCP) source.

The source electrode 376 receives RF power from the first RF power source 320 through the first matching unit 130 to form a capacitively coupled plasma (CCP) in the chamber 310.

Specifically, when RF power is applied to the source electrode 376 and to the wafer chuck 112 of the generating apparatus 300, an electric field is formed between the source electrode 376 and the wafer chuck 112. At the same time, when a reactive gas is injected into the chamber 310 through the gas supply unit 372 provided on an upper portion of the chamber 310, the reactive gas is changed into a plasma by the electric field in the chamber 310. Wafer processes such as etching or thin film deposition can be performed on a wafer by the generated plasma. Here, when RF power is applied in a pulse mode, plasma turn-on and turn-off operations are repeatedly performed according to the pulse frequencies, which vary the impedance of the chamber 310. To reduce reflected power generated due to impedance variations in the chamber 310, the first RF power source 320 supplies a first pulse power level and a different, second pulse power level at different times.

FIG. 4 illustrates a plasma generating apparatus 400 according to another embodiment of the inventive concept. In FIG. 4, the same reference numerals as in FIGS. 1 to 3 denote the same components, and for simplicity of description, a repeated description thereof will be omitted.

Referring to FIG. 4, the plasma generating apparatus 400 includes a chamber 410, a first RF power source 420, a first matching unit 130, a second RF power source 240, a second matching unit 150, and a power source connection unit 260.

A wafer chuck 112 may be disposed in a lower portion of the chamber 410, and a plasma generation unit 470 may be disposed in an upper portion of the chamber 410.

In some embodiments, the plasma generation unit 470 includes a gas supply unit 472, nozzles 474, an insulating plate 476, and antennas 471.

As illustrated in FIG. 4, the gas supply unit 472 may be integrally formed with the insulating plate 476. However, embodiments of the inventive concept are not limited thereto, and the gas supply unit 472 may be disposed outside of the chamber 410 separate from the insulating plate 476. The gas supply unit 472 may supply a reactive gas through the nozzles 474, and exhaust gas may be expelled through a gas exhaust unit 380 disposed in the chamber 410 to maintain the chamber 410 in a vacuum state.

In some embodiments, the first RF power source 420 may be an inductively coupled plasma (ICP) source.

The antenna 471 receives RF power from the first RF power source 420 through the first matching unit 130 to form an ICP within the chamber 410.

Hereinafter, a method of generating plasma by using the ICP generating apparatus 400 according to a current embodiment will be described in detail.

Gas in the chamber 410 is expelled by the gas exhaust unit 380 to put the chamber 410 in a vacuum state, which is then supplied with a reactive gas for generating plasma from the gas supply unit 472. Then, RF power received from the first RF power source 420 is supplied to the antennas 471. A magnetic field forms around the antennas 471 by the application of the RF power to the antennas 471, which induces the formation of an electric field within the chamber 410, and the induced electric field excites electrons to generate an ICP. The plasma electrons collide with neutral gas particles in the vicinity thereof to generate ions and radicals, and the generated ions and radicals may etch a wafer on the chuck or may be deposited on the wafer. Here, when RF power is supplied in a pulse mode, the plasma turn-on and turn-off operations are repeatedly performed based on the pulse frequencies. In particular, in a case of an ICP, the chamber impedance changes frequently, and thus reflected power needs to be stabilized. Accordingly, the first RF power source 420 supplies a first pulse power level and a different second pulse power level at different times.

In some embodiments, the insulating plate 476 is provided between the antennas 471 and the wafer chuck 112. The insulating plate 476 reduces capacitive coupling between the antennas 471 and the plasma to help transmit energy received from the first RF power source 420 to the plasma by inductive coupling.

The antenna 471 may have one or more spiral coils. However, embodiments of the inventive concept are not limited thereto, and the antenna 471 may have various shapes other than a spiral coil.

FIG. 5 illustrates an example of the first RF power source of a plasma generating apparatus according to the inventive concept being operated in a pulse mode. In FIG. 5, an X-axis represents the time t in seconds, and a Y-axis represents the power P in Watts.

Referring to FIG. 5, the first RF power source 120 supplies RF power in a pulse mode. That is, RF power is supplied during a pulse on-time To, and no RF power is supplied during a pulse off-time Tf. Thus, plasma is generated in the pulse on-time To, and the plasma dissipates in the pulse off-time Tf.

The frequency of the RF power supplied by the first RF power source 120 and the second RF power source 140 during the pulse on-time To may be approximately 13.56 MHz. However, embodiments of the inventive concept are not limited thereto, and the frequency of the RF power supplied by the first and second RF power sources 120, 140 during the pulse on-time To may be in a range of between about 1 MHz and about 100 MHz. In addition, the frequency of the RF power supplied by the first and second RF power sources 120, 140 during the pulse on-time To may have different values at different times, which will be described below in detail with reference to FIGS. 9 and 10.

A duty ratio may be, for example, equal to or greater than 50%. The duty ratio is a ratio between a pulse on-time and a pulse off-time in a signal. For example, a duty ratio of 60% means that a pulse on-time and a pulse off-time are 60% and 40%, respectively. In addition, a duty ratio of 50% means that a pulse on-time and a pulse off-time are the same.

The duty ratio may vary depending on the required wafer processing. When the duty ratio varies, characteristics of the pulse plasma being generated may vary. Accordingly, when a duty ratio (To/(To+TO) varies, a time T5 of the first pulse power level Po and a second pulse power level Po+P′ may vary.

During the pulse on-time To, the first RF power source 120 supplies the first pulse power level Po and a different, second pulse power level Po+P′ at different times.

Specifically, the second pulse power level Po+P′ is received from the moment each pulse is started, and the first pulse power level Po is received after a duration time elapse of T5. That is, the second pulse power level Po+P′ lasts for a duration time of T5.

The duration time T5 of the second pulse power level Po+P′ may be about 0.1 to about 1 ms. In some embodiments, the second pulse power level Po+P′ may be greater than the first level pulse power Po. That is, the relationship P′>0 may be satisfied.

As described above, the second pulse power level Po+P′, which is greater than the first pulse power level Po, is applied for a duration time of T5 from the moment each pulse is started, and thus a practical voltage applied inside the chamber at the initial stage of a pulse is increased, thereby reducing a generation delay for the plasma.

FIG. 6 illustrates another example of a first RF power source 120 of a plasma generating apparatus according to the inventive concept being operated in a pulse mode. In FIG. 6, an X-axis represents the time t in seconds, and a Y-axis represents the power P in Watts. Herein, a repeated description with regard to FIG. 5 will be omitted for the purpose of simplifying the description.

Referring to FIG. 6, the first RF power source applies RF power in a pulse mode. Thus, plasma is generated during a pulse on-time To, and plasma dissipates during a pulse off-time Tf.

During the pulse on-time To, the first RF power source supplies a first pulse power level Po and a different second pulse power level Po+P′ at different times.

Specifically, the first pulse power level Po is supplied from the moment each pulse is started to a time t′(s), the second pulse power level Po+P′ is supplied after the time t′(s), and the first pulse power level Po is supplied again from a time t′+T5(s).

The second pulse power level Po+P′ lasts for a duration time of T5. The duration time T5 of the second pulse power level Po+P′ may be about 0.1 to about 1 ms. In some embodiments, the second pulse power level Po+P′ may be received within 1 ms of each pulse start.

As described above, the second pulse power level Po+P′, which is greater than the first pulse power level Po, is received within 1 ms of each pulse start, and thus a practical voltage applied to the chamber at the initial stage of a pulse is increased, reducing a generation delay for the plasma. The time t′ when the second pulse power level Po+P′ starts may be determined based on the type of process being performed or the type of wafer being used.

FIG. 7 illustrates an example of a first RF power source 120 and the second RF power source 140 of a plasma generating apparatus according to an inventive concept being operated in a synchronized pulse mode. In FIG. 7, an X-axis represents the time t in seconds, and a Y-axis represents the power P in Watts.

Referring to FIG. 7, RF power S supplied by the first RF power source 120 and RF power B supplied by the second RF power source 140, both operated in a pulse mode. That is, RF power is supplied during a pulse on-time, and no RF power is supplied during a pulse off-time.

As described above with reference to FIGS. 5 and 6, the first RF power source supplies a first pulse power level and a different second pulse power level at different times during a pulse on-time To (see FIGS. 5 and 6).

As described in a current embodiment, the RF power B supplied by the second RF power source may have the same level during the pulse on-time To. However, embodiments of the inventive concept are not limited thereto. For example, similar to the RF power S supplied by the first RF power source, the RF power B supplied by the second RF power source may have a first pulse power level and a different second pulse power level at different times.

In some embodiments, a duty ratio of the RF power S supplied by the first RF power source and a duty ratio of the RF power B supplied by the second RF power source may equal each other. In addition, the RF power S supplied by the first RF power source and the RF power B supplied by the second RF power source may be synchronized with each other through the power source connection unit 260 (see FIG. 2).

FIG. 8 illustrates another example of the first RF power source 120 and the second RF power source 140 of the plasma generating apparatus according to the inventive concept being operated in a synchronized pulse mode. In FIG. 8, the same reference numerals as in FIG. 7 denote the same components, and a repeated description thereof will be omitted for the purpose of simplifying the description.

Referring to FIG. 8, RF power S supplied by the first RF power source and RF power B supplied by the second RF power source may be synchronized with each other through the power source connection unit 260 (see FIG. 2).

As illustrated in FIG. 8, the RF power B supplied by the second RF power source may follow the RF power S supplied by the first RF power source. In other words, the RF power B supplied by the second RF power source may be delayed by T8(s) with respect to the RF power S supplied by the first RF power source. However, embodiments of the inventive concept are not limited thereto, and the RF power S supplied by the first RF power source may follow the RF power B supplied by the second RF power source.

FIG. 9 is a graph of an example of the first RF power source of the plasma generating apparatus according to the inventive concept being operated in a pulse mode. In FIG. 9, an X-axis represents a time t in seconds, and a Y-axis represents a frequency f in Hertz.

Referring to FIG. 9, the first RF power source supplies RF power in a pulse mode. That is, RF power is supplied during a pulse on-time To, and no RF power is supplied during a pulse off-time Tf.

During the pulse on-time To, the first RF power source supplies a first pulse power frequency fo and a different second pulse power frequency fo+f′ at different times.

The second pulse power frequency fo+f′ is supplied at the moment each pulse is started. Specifically, the second pulse power frequency fo+f′ is supplied from the moment each pulse is started, and the second pulse power frequency fo+f′ has a duration of T9(s). The duration time T9 of the second pulse power frequency fo+f′ may be from about 0.1 to about 1 ms. The first pulse power frequency fo may be supplied during the pulse on-time To after the duration time T9 of the second pulse power frequency fo+f.

In some embodiments, the first RF power source may supply the same levels of pulse power during the pulse on-time To. In other embodiments, the first RF power source may supply different levels of power at different times (see FIGS. 5 and 6). In this case, the duration time T9 of the second pulse power frequency fo+f′ may be the same as the duration time T5 of the second pulse power level (see FIG. 5), but embodiments of the inventive concept are not limited thereto.

The first frequency fo may be approximately 13.56 MHz. However, embodiments of the inventive concept are not limited thereto, and the first frequency fo may be greater than or equal to about 1 MHz and less than or equal to about 100 MHz.

In some embodiments, the second frequency fo+f′ may have a value greater than the first frequency fo. That is, the relationship f>0 may be satisfied.

As described above, a second pulse power frequency fo+f′ having a higher frequency than the first pulse power frequency fo is applied for a duration time of T9 from the moment each pulse is started, which may reduce a time for matching impedance between the first RF power source 120 and the plasma generation unit 114.

FIG. 10 is a graph of another example of the first RF power source 120 of the plasma generating apparatus according to the inventive concept being operated in a pulse mode. In FIG. 10, the same reference numerals as in FIG. 9 denote the same components, and a repeated description thereof will be omitted for the purpose of simplifying the description.

Referring to FIG. 10, the first RF power source supplies RF power having different frequency values at different times during a pulse on-time To.

The first RF power source may supply RF power having a frequency in a range that is greater than or equal to about 1 Hz and less than or equal to a second frequency fo+f′ during a first section T10. The second frequency fo+f′ may be greater than or equal to about 13.56 MHz and less than or equal to about 100 MHz.

The duration of the first section T10 may be about 0 to about 1 ms. A first pulse power frequency fo may be supplied during a pulse on-time To after the first section T10.

As shown in FIG. 10, during the first section T10, the frequency of the RF power from the first RF power source increases substantially linearly from the first frequency fo to the second frequency fo+f′, and then decreases substantially linearly from the second frequency fo+f′ back to the first frequency fo, however, embodiments of the inventive concept are not limited thereto. The form of the frequency change during the first section T10 can vary depending on a frequency required to match impedance, and can vary based on the types of processes being performed or the type of wafer.

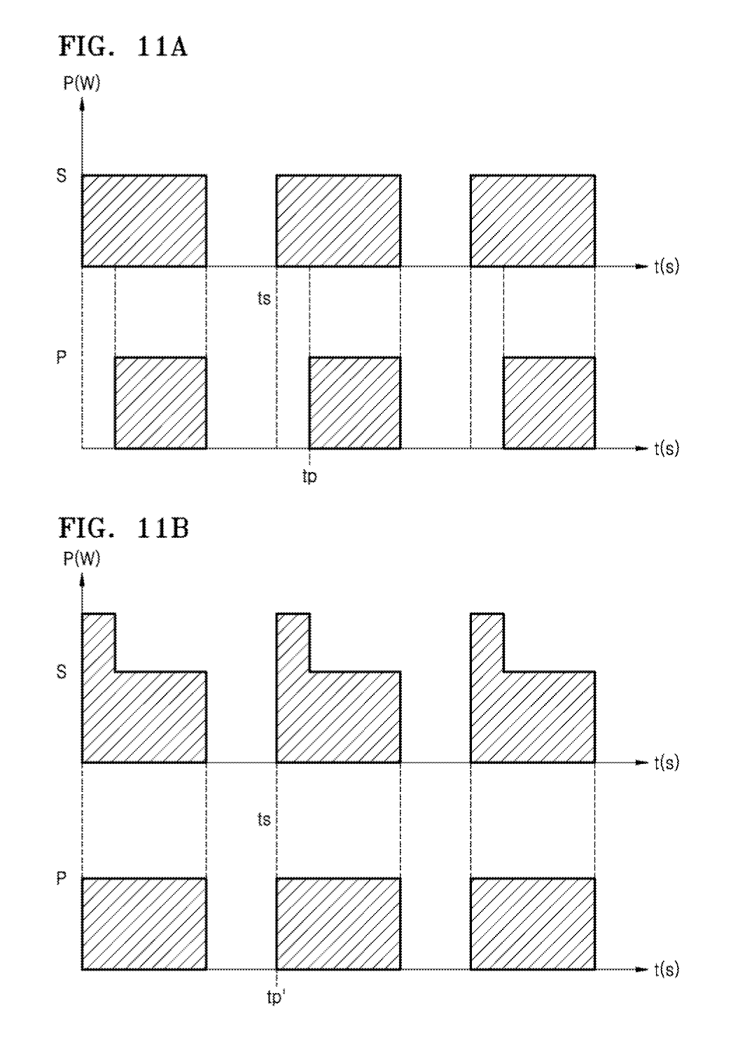

FIGS. 11A and 11B illustrate an improvement of pulse plasma generation characteristics of a plasma generating apparatus according to an embodiment of the inventive concept. In FIGS. 11A and 11B, an X-axis represents a time t in seconds, and a Y-axis represents power P in Watts.

Referring to FIG. 11A, RF power S supplied by a first RF power source has the same power level during a pulse on time. Pulse plasma P is generated through energy supplied by the pulse power.

In this case, a time (tp) when each pulse plasma is generated is delayed behind an RF pulse power generation-time(ts) due to reflected power. That is, plasma generation is delayed, and thus wafer processing efficiency is reduced. The generation or dissipation of plasma may determine whether light is emitted within the chamber 110, which may be determined by measuring light emitted through a viewport of the chamber using optical emission spectroscopy (OES).

Referring to FIG. 11B, the RF power S supplied by the first RF power source has different power levels at different times. Specifically, a second pulse power level is supplied from the moment each pulse is started, and then a first pulse power level is supplied.

As described above, a greater power is applied at an initial stage of each pulse, which increases a practical voltage transmitted to the chamber at the initial stage of a pulse, which reduces reflected power generated at the initial stage of a pulse and accordingly reduces a delay in the generation of each pulse plasma. That is, a stable pulse plasma may be generated by bringing a time(tp′) when each pulse plasma is generated closer to each RF pulse power generation-time(ts).

While embodiments of the inventive concept have been particularly shown and described with reference to exemplary embodiments thereof, it will be understood that various changes in form and details may be made therein without departing from the spirit and scope of the following claims.

1. A plasma generating apparatus comprising:
a chamber that encloses a reaction space that is isolated from the outside;
a wafer chuck disposed in a lower portion of the chamber;
a plasma generation unit disposed in an upper portion of the chamber;
a first radio-frequency (RF) power source configured to supply RF power to the plasma generation unit;
a first matching unit interposed between the first RF power source and the plasma generation unit;
a second RF power source configured to supply RF power to the wafer chuck; and
a second matching unit interposed between the second RF power source and the wafer chuck,
wherein the first RF power source supplies a first pulse power level and a different second pulse power level at different times.

2. The plasma generating apparatus of claim 1, wherein the second pulse power level is greater than the first pulse power level.

3. The plasma generating apparatus of claim 1, wherein a duration time of the second level pulse power is from about 0.1 to about 1 ms.

4. The plasma generating apparatus of claim 1, wherein the second pulse power level is supplied within about 1 ms after the start of each pulse generated by the first RF power.

5. The plasma generating apparatus of claim 1, wherein the first RF power source and the second RF power source are synchronized with each other.

6. The plasma generating apparatus of claim 5, further comprising a power source connection unit connected to the first RF power source and to the second RF power source that is configured to synchronize the first RF power source and the second RF power source.

7. The plasma generating apparatus of claim 1, wherein the first RF power source is a capacitively coupled plasma (CCP) source.

8. The plasma generating apparatus of claim 1, wherein the first RF power source is an inductively coupled plasma (ICP) source.

9. The plasma generating apparatus of claim 8, wherein the plasma generation unit further comprises an antenna connected to the first RF power source with the first matching unit interposed therebetween, and an insulating plate between the antenna and the wafer chuck.

10. A plasma generating apparatus comprising:
a chamber that encloses a reaction space that is isolated from the outside;
a wafer chuck disposed in a lower portion of the chamber;
a plasma generation unit disposed in an upper portion of the chamber;
a first radio-frequency (RF) power source configured to supply RF power to the plasma generation unit;
a first matching unit interposed between the first RF power source and the plasma generation unit;
a second RF power source configured to supply RF power to the wafer chuck; and
a second matching unit interposed between the second RF power source and the wafer chuck,
wherein the first RF power source supplies a first pulse power frequency and a different second pulse power frequency at different times.

11. The plasma generating apparatus of claim 10, wherein the second pulse power frequency is applied when each pulse generated by the first RF power source starts, to reduce a time for matching impedance between the first RF power source and the plasma generation unit.

12. The plasma generating apparatus of claim 10, wherein a frequency of the second pulse power frequency is higher than a frequency of the first pulse power frequency.

13. The plasma generating apparatus of claim 10, wherein a duration of the second pulse power frequency is from about 0.1 to about 1 ms.

14. The plasma generating apparatus of claim 10, wherein the first RF power source supplies a first pulse power level and a different second pulse power level at different times.

15. The plasma generating apparatus of claim 10, wherein a duration of the second pulse power frequency is the same as a duration of the second pulse power level.

16-20. (canceled)
